(19) United States
(12) Patent Application Publication
(10) Pub. No.: US 2008/0318388 A1
(43) Pub. Date: Dec. 25, 2008

(54) METHOD FOR FABRICATING MOS TRANSISTOR WITH RECESS CHANNEL

(76) Inventors: Shian-Jyh Lin, Taipei County (TW); Yu-Pi Lee, Taipei County (TW); Jar-Ming Ho, Taipei City (TW); Shun-Fu Chen, Taipei County (TW); Tse-Chuan Kuo, Taipei City (TW)

Correspondence Address: NORTH AMERICA INTELLECTUAL PROPERTY CORPORATION, P.O. BOX 506, MERRIFIELD, VA, 22116, US

(21) Appl. No.: 11/955,405

(22) Filed: Dec. 13, 2007

(30) Foreign Application Priority Data
Jun. 20, 2007 (TW) 096122038

(51) Int. Cl. H01L 21/20

(52) U.S. Cl. 438/386; 257/E21.09

(57) ABSTRACT

A method for fabricating a MOS transistor with a recess channel, including: providing a substrate with a plurality of trench capacitors therein, wherein a trench top oxide is positioned on top of each trench capacitor and extended away from the substrate surface; forming a first spacer on side walls of the trench top oxide; forming a second spacer on the first spacer; defining a plurality of active areas, wherein each of the active areas is parallel with each other and comprises at least two of the trench capacitors; forming an isolation area between each of the active area; etching the substrate of the active area by using the second spacer as a mask to form a trench in the active area; removing the second spacer to expose a portion of the substrate, and etching the exposed substrate to enlarge the trench; and forming a gate structure in the trench.

### BACKGROUND OF THE INVENTION

1. Field of the Invention

The present invention relates to a method for fabricating a MOS transistor with a recess channel, and more particularly, to a method for fabricating a MOS transistor having a recess ultra deep round corner device.

2. Description of the Prior Art

Dimensions of integrated circuit devices are continually being shrunk in order to increase speed, make the device more portable and reduce the cost of manufacturing the device. Certain designs have a minimum feature size. For example, dynamic random access memory devices (DRAMs), which use vertical metal oxide semiconductor field effect transistors (MOSFETs) with deep trench (DT) storage capacitors, have a minimum feature size of approximately 70 nm˜0.15 μm. Below this size, the internal electric fields will exceed the upper limit for storage node leakage and the retention time will be lower than an acceptable level at the same time. Therefore, a different method and/or a different structure to further reduce the size of integrated circuit devices is required.

Sub-micron scale MOS transistors have to overcome many technical challenges when keeping reducing the device size. As the MOS transistors become narrower than ever, i.e. their channel length decreases, problems such as junction leakage, source/drain breakdown voltage, and data retention time become more pronounced.

One way to decrease the physical dimension of ULSI circuits is to form recessed-gate or “trench-type” transistors, which have a gate electrode buried in a groove formed in a semiconductor substrate. This type of transistor reduces short channel effects by effectively lengthening the effective channel length by having the gate extend into the semiconductor substrate.

The recessed-gate MOS transistor has a gate insulation layer formed on a sidewall and a bottom surface of a recess, which is etched into a substrate with a conductive substance filling in, as compared to a planar gate type transistor having a gate electrode formed on a planar surface of a substrate.

The aforementioned recessed-gate technology has some shortcomings. For example, since the recess-gate MOS transistor has a longer gate channel length, the transistor driving voltage will be increased and the transistor driving current will be smaller.

### SUMMARY OF THE INVENTION

It is one objective of this invention to provide a method for fabricating a MOS transistor with a recess channel in order to solve the abovementioned problems.

According to the claimed invention, a method for fabricating a MOS transistor with a recess channel includes the steps of: providing a substrate with a plurality of trench capacitors therein, wherein a trench top oxide is positioned on top of each trench capacitor and extended away from a face of the substrate; forming a first spacer on side walls of the trench top oxide; forming a second spacer on the first spacer; defining a plurality of active areas, wherein each of the active areas is parallel with each other and comprises at least two of the trench capacitors; forming an isolation area between each of the active area; etching the substrate of the active area by using the second spacer as a mask to form a trench in the active area; removing the second spacer to expose a portion of the substrate, and etching the exposed substrate to enlarge the trench; and forming a gate structure in the trench.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIGS. 1-3 are schematic, cross-sectional diagrams illustrating an exemplary method of fabricating a recessed channel MOS transistor device in accordance with the preferred embodiment of this invention.

FIG. 4 is a schematic top view showing the layout of deep trench capacitors in a memory array area according to this invention.

FIGS. 5-6 are schematic, cross-sectional diagrams illustrating an exemplary method of fabricating a recessed channel MOS transistor device in accordance with the preferred embodiment of this invention.

FIGS. 7-8 are schematic, three-dimensional diagrams illustrating an exemplary method of fabricating a recessed channel MOS transistor device in accordance with the preferred embodiment of this invention.

FIGS. 9-11 are schematic, cross-sectional diagrams illustrating an exemplary method of fabricating a recessed channel MOS transistor device in accordance with the preferred embodiment of this invention.

FIG. 12 is a schematic, three-dimensional diagram illustrating an exemplary method of fabricating a recessed channel MOS transistor device in accordance with the preferred embodiment of this invention.

FIGS. 13-14 show the A-A′ cross-sectional structure in FIG. 12.

FIG. 15 shows the B-B′ cross-sectional structure in FIG. 12.

### DETAILED DESCRIPTION

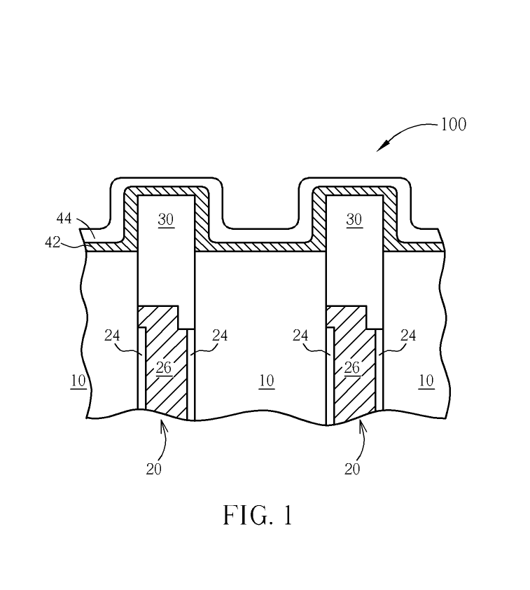

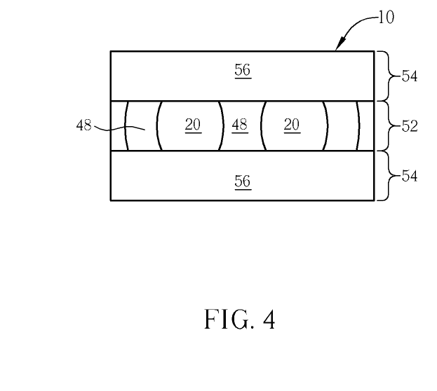

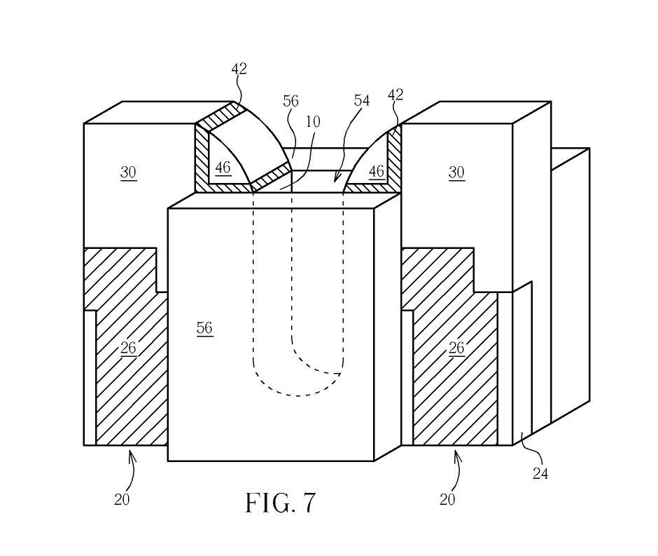

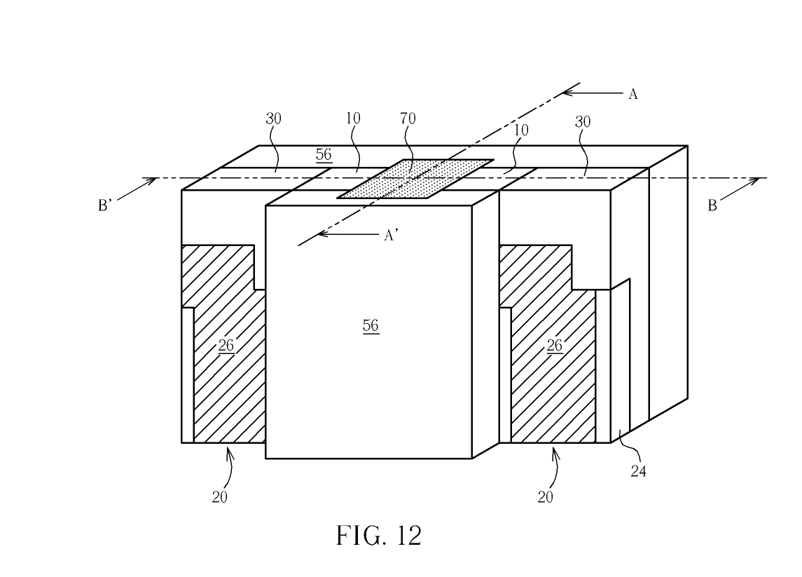

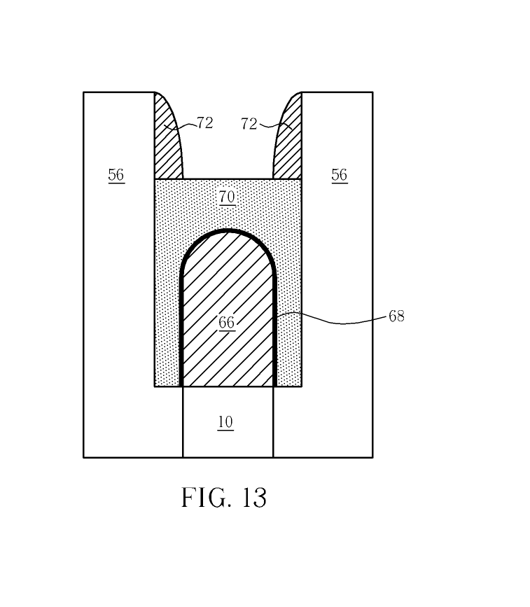

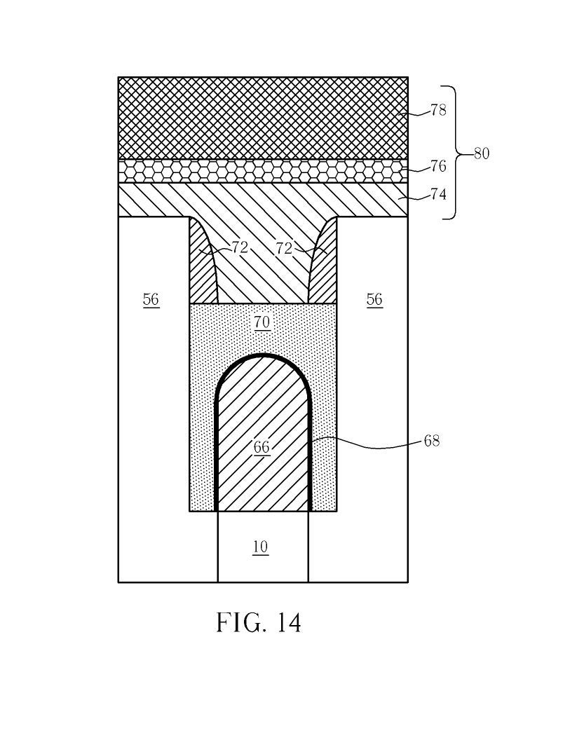

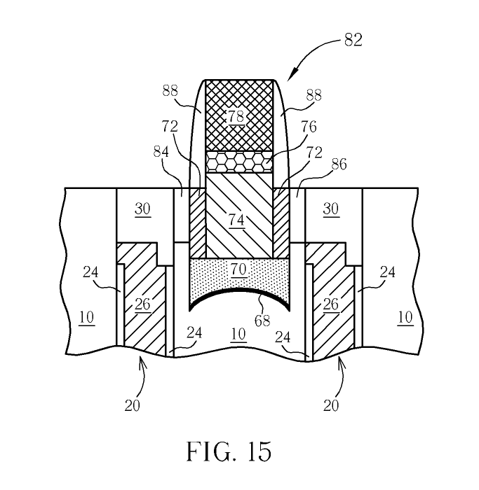

Please refer to FIGS. 1-15. FIGS. 1-3, 5-6, and 9-11 are schematic, cross-sectional diagrams illustrating an exemplary method for fabricating a MOS transistor with a recess channel in accordance with the preferred embodiment of this invention. FIG. 4 is a schematic top view showing the layout of the deep trench capacitors in the memory array area according to this invention. FIGS. 7-8 and 12 are schematic, three-dimensional diagrams illustrating an exemplary method of fabricating a recessed channel MOS transistor device in accordance with the preferred embodiment of this invention. FIGS. 13-14 show the A-A′ cross-sectional structure in FIG. 12. FIG. 15 shows the B-B′ cross-sectional structure in FIG. 12.

As shown in FIG. 1, a semiconductor substrate 10 has a memory array area 100. The memory array area 100 of the semiconductor substrate 10 has deep trench capacitors 20 fabricated using a Single-Sided Buried Strap (SSBS) process. The doped polysilicon 26 functions as one electrode of the deep trench capacitor 12. The deep trench capacitor 20 includes a sidewall capacitor dielectric layer 24 and a doped polysilicon layer 26, and the doped polysilicon layer 26 is used as a connection layer of the deep trench capacitor 20. The method of fabricating the deep trench capacitor 20 is known in the art. For the sake of simplicity, only the upper portions of the deep trench capacitor 20 are shown in the figures. It is understood that the deep trench capacitor 20 further comprises a buried plate and an upper electrode, which is not shown. Additionally, there is a trench top oxide (TTO) 30 on each deep trench capacitor 20, wherein the material of the TTO 30 can be SiO (for example). A silicon nitride liner 42 and a dielectric layer 44 such as tetra-ethyl-ortho-silicate (TEOS) are deposited on the memory array area 100 of the semiconductor substrate 10 in sequence. A photoresist layer 130 is formed, the memory array area 100 is opened by a lithography process.

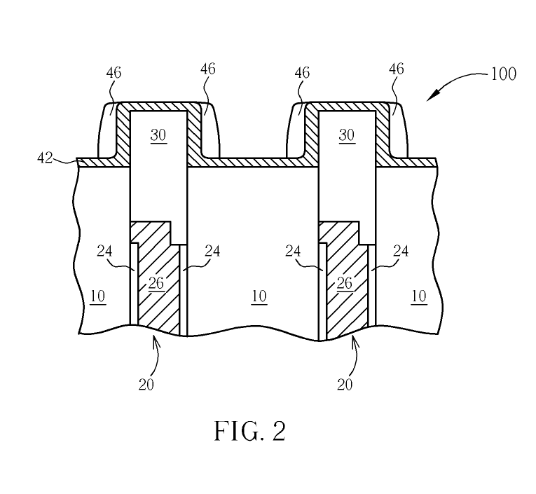

Next, as shown in FIG. 2, an anisotropic dry etching process is performed to etch the dielectric layer 44 and form a first spacer 46 surrounding the TTO 30.

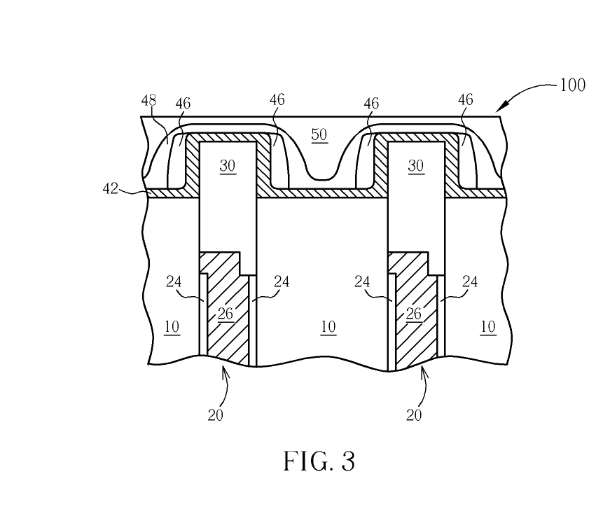

As shown in FIG. 3, an LPTEOS layer 48 is formed on the memory array area 100 of the semiconductor substrate 10.

As shown in FIG. 4, the following steps are performed to define the active areas 52 and shallow trench isolation (STI) areas 54 on the semiconductor substrate 10 and form a plurality of STI structures 56: (1) deposition of a boron doped silicate glass (BSG) layer; (2) deposition of a polysilicon layer; (3) lithographic and etching process for defining the active areas in the support circuit region; (4) oxidation for oxidizing the active areas in the support circuit region; and (5) trench filling for the STI and chemical mechanical polishing. Please note the steps are not limited to those detailed here.

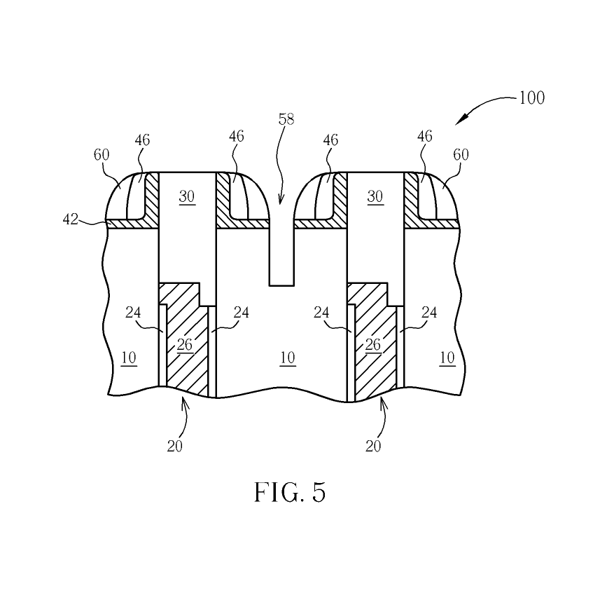

Next, as shown in FIG. 5, an etching process is performed to etch the LPTEOS layer 48 to form a second spacer 60 in the semiconductor substrate 10 between the deep trench capacitors 20, and then the second spacer 60 is used as a hard mask to form an opening 58, wherein the opening 58 has a width of about 10˜100 nm and a depth of about 30˜3000 nm.

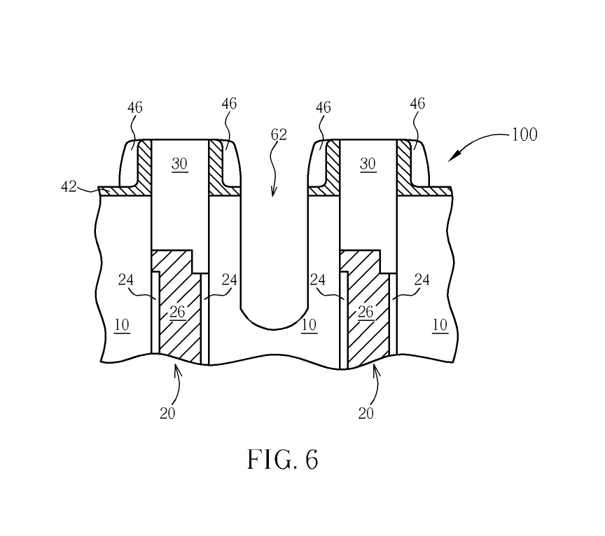

As shown in FIG. 6, an anisotropic dry etching process is performed to use the first spacer 46 and the TTO 30 as a hard mask to etch the opening 58 to form a recessed channel 62. At the same time, the second spacer 60 is also removed. The recessed channel 62 has a width of about 20˜200 nm. The materials of the first spacer 46 and the second spacer 60 can be the same or different.

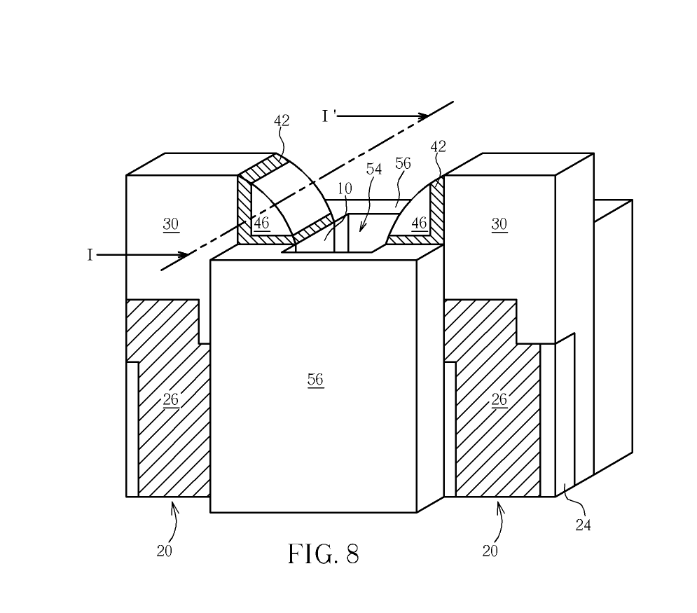

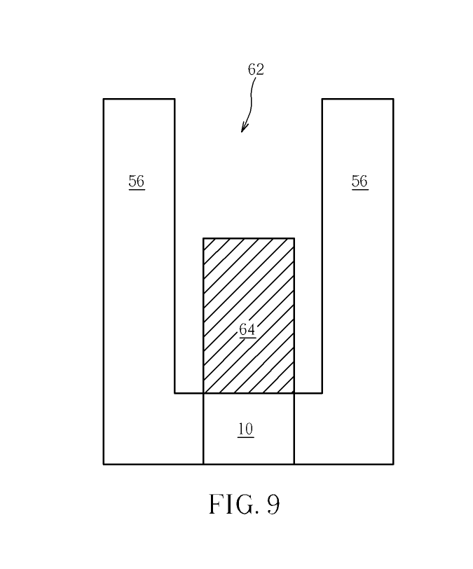

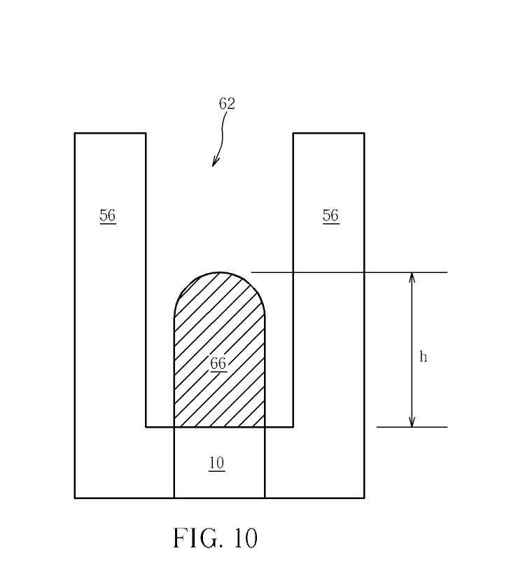

Next, as shown in FIG. 8, a wet etching process and dry etching process are performed to strip off a part of the STI structures 56 in two sides of the recessed channel 62 to let the top surface of the STI structures 56 be lower than the bottom of the recessed channel 62, so as to form a fin structure 64 extended away from the top surface of the part of the STI structures 56. Please refer to FIG. 9. FIG. 9 shows the I-I′ cross-sectional structure in FIG. 8. As shown in FIG. 10, an isotropic dry etching process or a wet etching process is performed to corner round the fin structure 64 to form a recess ultra deep round corner device 66. Additionally, a width and a depth h of the recessed channel 62 can be adjusted when corner rounding the fin structure 64, wherein the depth h can be greater than 5 nm. However, this is only for illustrative purposes and is not meant to be a limitation of the present invention. The depth h can be flexibly adjusted according to different requirements of the components.

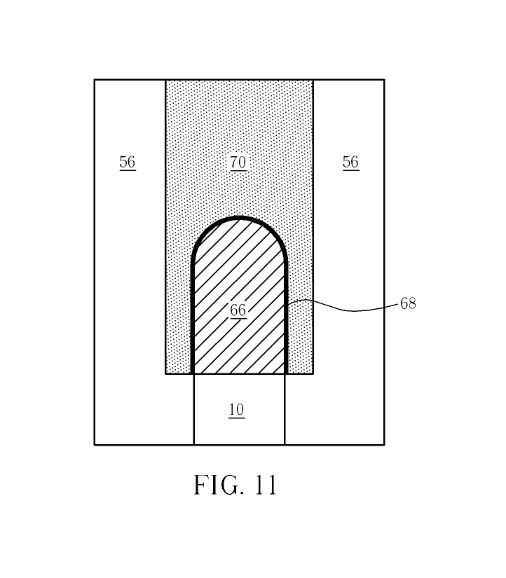

As shown in FIG. 11, a gate dielectric layer 68 is formed on the recess ultra deep round corner device 66 to finish a fin channel, and then a gate material layer 70 is formed on the top surface of the part of the STI structures 56 and the gate dielectric layer 68, wherein materials of the gate material layer 70 can include polysilicon, W, HfN, MoN, HfMo, HfMoN, TiN, TaN, and AlN, and the recess ultra deep round corner device 66 can be made of SiOx. Next, a planarization process such as a chemical mechanical polishing (CMP) process is carried out to planarize the main surface of the semiconductor substrate 10. Please refer to FIG. 12. FIG. 12 is a schematic, three-dimensional diagram of FIG. 11.

In addition, please refer to FIG. 13. FIG. 13 shows the A-A′ cross-sectional structure in FIG. 12. The present invention can further etch back the gate material layer 70, and then form a third spacer 72 on the sidewall of the STI structure 56. Next, please refer to FIG. 14. FIG. 14 also shows the A-A′ cross-sectional structure in FIG. 12. As shown in FIG. 14, a polysilicon layer 74, a tungsten layer 76, and a silicon nitride layer 78 are deposited on the gate material layer 70, the STI structures 56, and then the third spacers 72 are formed in sequence to form a gate conducting structure layer 80. In addition, please note that the above composition of the gate conducting structure layer 80 is only for illustrative purposes and is not meant to be a limitation of the present invention. For example, the gate conducting structure layer 80 can also just comprise the polysilicon layer 74 and the silicon nitride layer 78.

Next, a lithography process and an etching process are performed to form a gate stack structure 82 above the gate material layer 70, and ion implantation processes are performed to form a source 84 and a drain 86, and finally a fourth spacer 8 is formed on a sidewall of the gate stack structure 82, as shown in FIG. 15. FIG. 15 shows the B-B′ cross-sectional structure in FIG. 12.

In brief, since the recessed channel MOS transistor device of the present invention has the recess ultra deep round corner device 66, the transistor driving voltage and the transistor driving current will be controlled efficiently under a condition with a longer gate channel length.

Those skilled in the art will readily observe that numerous modifications and alterations of the device and method may be made while retaining the teachings of the invention.

What is claimed is:

1. A method for fabricating a MOS transistor with a recess channel, comprising the steps of:
providing a substrate with a plurality of trench capacitors therein, wherein a trench top oxide is positioned on top of each trench capacitor and extended away from a face of the substrate;
forming a first spacer on side walls of the trench top oxide;
forming a second spacer on the first spacer;
defining a plurality of active areas, wherein each of the active areas is parallel with each other and comprises at least two of the trench capacitors;
forming an isolation area between the two adjacent active areas;
forming a trench in the substrate of the active area;
removing the second spacer to partially expose the substrate so as to enlarge the trench; and
forming a gate structure in the trench.

2. The method of claim 1, wherein the step of forming the gate structure in the trench further comprising:
partially etching the isolation area in two sides of the trench to form a fin structure.

3. The method of claim 2, wherein the step of forming the gate structure in the trench further comprising:
forming a gate dielectric layer to enclose the fin structure; and
filling a gate material in the trench.

4. The method of claim 2, wherein the step of partially etching the isolation area further comprising:
rounding the fin structure to form a rounded fin structure.

5. The method of claim 3 further comprising forming a gate stack structure over the gate material.

6. The method of claim 5, wherein the gate stack structure comprises a polysilicon layer, a tungsten layer, and a silicon nitride layer formed in sequence over the gate material.

7. The method of claim 1, wherein the trench is enlarged by etching.

8. The method of claim 7, wherein the trench is defined by using the second spacer as a mask.
